(19) United States
(12) Patent Application Publication
(10) Pub. No.: US 2024/0052240 A1
(43) Pub. Date: Feb. 15, 2024

(54) OXIDE FLUORESCENT MATERIAL, LIGHT EMITTING DEVICE, AND METHOD FOR PRODUCING OXIDE FLUORESCENT MATERIAL

(71) Applicant: NICHIA CORPORATION, Anan-shi (JP)

(72) Inventor: Yoshinori MURAZAKI, Komatsushima-shi (JP)

(73) Assignee: NICHIA CORPORATION, Anan-shi (JP)

(21) Appl. No.: 18/259,267

(22) PCT Filed: Nov. 8, 2021
(86) PCT No.: PCT/JP2021/041001

§ 371 Date: Jun. 23, 2023

(30) Foreign Application Priority Data
Dec. 24, 2020 (JP) 2020-215564
Nov. 4, 2021 (JP) 2021-180133

(51) Int. Cl. C09K 11/68; C01G 17/00; C09K 11/77; C09K 11/66; H01L 33/50

(52) U.S. Cl. CPC C09K 11/684; C01G 17/006; C09K 11/7739; C09K 11/77342; C09K 11/7774; C09K 11/77348; C09K 11/665; C09K 11/7708; H01L 33/504; H01L 33/502; C01P 2002/54; C01P 2006/60; H01S 5/0087

(57) ABSTRACT

Provided is an oxide fluorescent material having a light emission peak in a wavelength range from red light to near-infrared light.

The oxide fluorescent material has a composition including: a first element M¹ being at least one element selected from the group consisting of Li, Na, K, Rb, and Cs; a second element M² being at least one element selected from the group consisting of Ca, Sr, Mg, Ba, and Zn; Ge; O (oxygen); and Cr, the composition optionally including: a third element M³ being at least one element selected from the group consisting of Si, Ti, Zr, Sn, Hf, and Pb; and a fourth element M⁴ being at least one element selected from the group consisting of Eu, Ce, Tb, Pr, Nd, Sm, Yb, Ho, Er, Tm, Ni, and Mn. When the molar ratio of Ge, or the total molar ratio of the third element M³ and Ge in the case of comprising the third element M³, in 1 mol of the composition of the oxide fluorescent material is 6, the molar ratio of the first element M¹ is 1.5 or more and 2.5 or less, the molar ratio of the second element M² is 0.7 or more and 1.3 or less, the molar ratio of the third element M³ is 0 or more and 0.4 or less, the molar ratio of O (oxygen) is 12.9 or more and 15.1 or less, and the molar ratio of Cr is 0.2 or less. The oxide fluorescent material has a light emission peak wavelength of 700 nm or more and 1,050 nm or less in a light emission spectrum of the oxide fluorescent material.

### TECHNICAL FIELD

The present disclosure relates to an oxide fluorescent material, a light emitting device, and a method for producing an oxide fluorescent material.

### BACKGROUND ART

Light emitting devices having light emission intensity in a wavelength range from red light to near-infrared light are desired to be used in, for example, infrared cameras, infrared communications, light sources for plant growth and cultivation, vein authentication that is one type of biometric authentication, and food component analyzers that non-destructively measure the sugar content of foods such as fruits and vegetables. Light emitting devices configured to emit light in the wavelength range from red light to near-infrared light as well as in a wavelength range of visible light are also desired.

Examples of such light emitting devices include a light emitting device in which a light emitting diode (LED) and a fluorescent material are combined.

Examples of the fluorescent material to be combined in the light emitting device include a fluorescent material having a relatively large light emission intensity of the light emission spectrum in the wavelength range from red light to near-infrared light (hereinafter, also referred to as “near-infrared light emitting fluorescent material”).

As the near-infrared light emitting fluorescent material, Patent Literature 1 discloses a fluorescent material having a light emission peak wavelength in a wavelength range of 680 nm or more and 760 nm or less and having a composition represented by, for example, CaYAlO₄:Mn⁴⁺. Near-infrared light emitting fluorescent materials with a light emission spectrum having a wide full width at half maximum and a light emission peak wavelength in a longer wavelength range, which are suitable for each application described above, may be required.

### CITATION LIST

### Patent Literature

Patent Literature 1: Japanese Translation of PCT International Application Publication No. 2020-528486

### SUMMARY OF THE INVENTION

### Problem to be Solved by the Invention

The present disclosure has an object to provide an oxide fluorescent material having a light emission peak wavelength in a wavelength range from red light to near-infrared light and having a wider full width at half maximum of the light emission spectrum, a light emitting device using the same, and a method for producing an oxide fluorescent material.

### Means for Solving Problem

A first aspect of the present disclosure is an oxide fluorescent material having a composition that includes: a first element M¹ being at least one element selected from the group consisting of Li, Na, K, Rb, and Cs; a second element M² being at least one element selected from the group consisting of Ca, Sr, Mg, Ba, and Zn; Ge; O (oxygen); and Cr, the composition optionally including: a third element M³ being at least one element selected from the group consisting of Si, Ti, Zr, Sn, Hf, and Pb; and a fourth element M⁴ being at least one element selected from the group consisting of Eu, Ce, Tb, Pr, Nd, Sm, Yb, Ho, Er, Tm, Ni, and Mn. When the molar ratio of Ge, or the total molar ratio of the third element M³ and Ge in the case of comprising the third element M³, in 1 mol of the composition of the oxide fluorescent material is 6, the molar ratio of the first element M¹ is 1.5 or more and 2.5 or less, the molar ratio of the second element M² is 0.7 or more and 1.3 or less, the molar ratio of the third element M³ is 0 or more and 0.4 or less, the molar ratio of O (oxygen) is 12.9 or more and 15.1 or less, and the molar ratio of Cr is 0.2 or less. The oxide fluorescent material has a light emission peak wavelength of 700 nm or more and 1,050 nm or less in a light emission spectrum of the oxide fluorescent material.

A second aspect of the present disclosure is a light emitting device including the oxide fluorescent material and a light emitting element having a light emission peak wavelength of 365 nm or more and 500 nm or less to irradiate the oxide fluorescent material with light.

A third aspect of the present disclosure is a method for producing an oxide fluorescent material including: preparing a first compound containing a first element M¹ being at least one element selected from the group consisting of Li, Na, K, Rb, and Cs, a second compound containing a second element M² being at least one element selected from the group consisting of Ca, Sr, Mg, Ba, and Zn, a fifth compound containing Ge, a sixth compound containing Cr, optionally a third compound containing a third element M³ being at least one element selected from the group consisting of Si, Ti, Ge, Zr, Sn, Hf, and Pb, and optionally a fourth compound containing a fourth element M⁴ being at least one element selected from the group consisting of Eu, Ce, Tb, Pr, Nd, Sm, Yb, Ho, Er, Tm, Ni, and Mn; adjusting and mixing the first compound, the second compound, the fifth compound, the sixth compound, and optionally the third compound and/or the fourth compound to prepare a raw material mixture such that, when the molar ratio of Ge, or the total molar ratio of the third element M³ and Ge in the case of comprising the third element M³, in 1 mol of the composition of the oxide fluorescent material is 6, the molar ratio of the first element M¹ is 1.5 or more and 2.5 or less, the molar ratio of the second element M² is 0.7 or more and 1.3 or less, and the molar ratio of Cr is 0.2 or less; and heat-treating the raw material mixture at a temperature 900° C. or higher and 1,200° C. or lower in an atmosphere containing oxygen to obtain an oxide fluorescent material. At least one selected from the group consisting of the first compound, the second compound, the fifth compound, and the sixth compound is an oxide.

### Effect of the Invention

The present disclosure is capable of providing an oxide fluorescent material having a light emission peak wavelength in a wavelength range from red light to near-infrared light and having a wider full width at half maximum of the light emission spectrum, a light emitting device using the same, and a method for producing an oxide fluorescent material.

### BRIEF DESCRIPTION OF DRAWINGS

FIG. 1 is a schematic cross-sectional view showing an exemplary light emitting device according to a first embodiment of the present disclosure.

FIG. 2 is a schematic cross-sectional view showing another exemplary light emitting device according to the first embodiment of the present disclosure.

FIG. 3A is a schematic plan view showing an exemplary light emitting device according to a second embodiment of the present disclosure.

FIG. 3B is a schematic cross-sectional view showing an exemplary light emitting device according to the second embodiment of the present disclosure.

FIG. 4 is a graph showing a light emission spectrum of the oxide fluorescent material according to Example 1.

FIG. 5 is a graph showing a light emission spectrum of the oxide fluorescent material according to Example 2.

FIG. 6 is a graph showing a light emission spectrum of the oxide fluorescent material according to Example 3.

FIG. 7 is a graph showing a light emission spectrum of the oxide fluorescent material according to Example 4.

FIG. 8 is a graph showing a light emission spectrum of the oxide according to Comparative Example 1.

FIG. 9 is a graph showing excitation spectra of the oxide fluorescent material according to Example 1 and an aluminate fluorescent material (Y₃Al₅O₁₂:Ce).

FIG. 10 is a graph showing excitation spectra of the oxide fluorescent material according to Example 2 and an aluminate fluorescent material (Y₃Al₅O₁₂:Ce).

FIG. 11 is a graph showing reflection spectra of the oxide fluorescent materials according to Examples 1 and 2.

FIG. 12 is a graph showing light emission spectra of the light emitting devices according to Examples 1 to 3.

FIG. 13 is a graph showing light emission spectra of the light emitting devices according to Examples 4 and 5.

FIG. 14 is a graph showing a light emission spectrum of the light emitting device according to Comparative Example 1.

FIG. 15 is an enlarged graph of a part of the light emission spectrum of the light emitting device according to Comparative Example 1.

### MODE(S) FOR CARRYING OUT THE INVENTION

The oxide fluorescent material, the light emitting device using the same, and the method for producing an oxide fluorescent material according to the present disclosure will be hereunder described. The embodiments described below are intended to embody the technical idea of the present disclosure, and the present disclosure is not limited to the following oxide fluorescent material, the light emitting device, and the method for producing an oxide fluorescent material. For visible light, the relationship between color names and chromaticity coordinates, and the relationship between wavelength ranges of light and color names of monochromic light are in accordance with Japanese Industrial Standard (JIS) Z8110.

Light emitting devices using a fluorescent material are required to emit light in an appropriate wavelength range according to a visual object and usage conditions. For example, in medical practice, it is sometimes necessary to easily obtain information in a living body. The living body includes, for example, water, hemoglobin, and melanin as light absorbers. For example, hemoglobin has a high light absorptance in a visible light wavelength range of less than 650 nm, and with a light emitting device that emits light in the visible light wavelength range, it is difficult for light in the visible light wavelength range to transmit through the living body, which makes difficult to obtain information in the living body. In this regard, there is a wavelength range called a “living body window” where light easily transmits through the living body. A light emitting device that emits light in a near-infrared light wavelength range of, for example, 650 nm or more and 1,050 nm or less, including at least a portion of the wavelength range called the “living body window”, may be required. For example, when the increase or decrease in oxygen concentration in the blood in the living body can be measured by measuring the increase or decrease in light absorption of hemoglobin that binds to oxygen, the information in the living body can be easily obtained by irradiating light emitted from the light emitting device. Therefore, the fluorescent material used in the light emitting device may be required to have a light emission peak wavelength of 650 nm or more and 1,050 nm or less.

For example, food fields require non-destructive sugar content meters for measuring the sugar content of fruits and vegetables in a non-destructive manner, and non-destructive taste meters for rice. Near-infrared spectroscopy may be used as a non-destructive method for measuring internal quality of fruits and vegetables, such as sugar content, acidity, ripeness, and internal damage, as well as surface quality appearing on the skin surface of fruits and vegetables or in the surface layer near the skin surface, such as abnormal drying. In the near-infrared spectroscopy, fruits and vegetables are irradiated with light in the near-infrared light wavelength range, and the transmitted light that is transmitted through the fruits and vegetables and the reflected light that is reflected by the fruits and vegetables are received to measure the quality of the fruits and vegetables by measuring the decrease in light intensity (light absorption). Near-infrared spectroscopy analysis devices used in such food fields use a light source such as tungsten lamp or xenon lamp. In the present specification, the wavelength range of red light is in accordance with JIS Z8110.

It is also desirable to stably supply plants such as vegetables and to increase the production efficiency of plants under environmental changes such as climate change. Plant factories that can be artificially controlled can stably supply safe vegetables to the market and are expected as a next-generation industry. Such plant factories require a light emitting device that emits light capable of promoting the growth of plants. Reaction of plants to light can be grouped into photosynthesis and photomorphogenesis. Photosynthesis is a reaction that uses light energy to decompose water, generates oxygen, and fixes carbon dioxide to organic materials, which is a necessary reaction for the growth of plants. Photomorphogenesis is a morphogenetic reaction that uses light as a signal for seed germination, differentiation (germination formation, leaf formation), movement (pore opening and closing, chloroplast movement), and photorefraction. In the photomorphogenesis reaction, it has been found that light having a wavelength of 690 nm or more and 800 nm or less affects the photoreceptors of plants. Therefore, light emitting devices used in plant factories may be required to be capable of irradiating light in the wavelength range that affects plant photoreceptors (chlorophyll a, chlorophyll b, carotenoids, phytochromes, cryptochromes, and phototropins) and promotes the growth of plants.

As for the above-mentioned near-infrared light emitting fluorescent material, when the light emitting device uses a light emitting element such as a blue light emitting diode (LED) or laser diode (LD) that emits purple to blue light as an excitation light source, there is also room to improve the light emission characteristics of the fluorescent material so as to be able to emit light suitable for the intended use.

There is a case in which a light emitting device configured to emit light in the wavelength range of 700 nm or more and 1,050 nm or less and in the wavelength range of 365 nm or more and less than 700 nm is required. For example, it is sometimes necessary to emit light in the visible light wavelength range not only to obtain internal information on living bodies and fruits and vegetables, but also to enhance the visibility of objects. For example, a reflection spectroscopic measuring device used for measuring film thickness sometimes require a light emitting device that emits light with a light emission intensity of 10% or more relative to the maximum light emission intensity in the light emission spectrum over a wide wavelength range including a part of the visible light wavelength range of 365 nm or more and less than 700 nm to a part of the near-infrared light wavelength range of 700 nm or more and 1,050 nm or less.

### Oxide Fluorescent Material

The oxide fluorescent material has a composition that includes: a first element M¹ being at least one element selected from the group consisting of Li, Na, K, Rb, and Cs; a second element M² being at least one element selected from the group consisting of Ca, Sr, Mg, Ba, and Zn; Ge; O (oxygen); and Cr, and that optionally includes a third element M³ being at least one element selected from the group consisting of Si, Ti, Zr, Sn, Hf, and Pb, and a fourth element M⁴ being at least one element selected from the group consisting of Eu, Ce, Tb, Pr, Nd, Sm, Yb, Ho, Er, Tm, Ni, and Mn. When the molar ratio of Ge, or the total molar ratio of the third element M³ and Ge in the case of including the third element M³, in 1 mol of the composition of the oxide fluorescent material is 6, the molar ratio of the first element M¹ is 1.5 or more and 2.5 or less, the molar ratio of the second element M² is 0.7 or more and 1.3 or less, the molar ratio of the third element M³ is 0 or more and 0.4 or less, the molar ratio of O (oxygen) is 12.9 or more and 15.1 or less, and the molar ratio of Cr is 0.2 or less. The oxide fluorescent material has a light emission peak wavelength of 700 nm or more and 1,050 nm or less in a light emission spectrum of the oxide fluorescent material. The oxide fluorescent material is adapted to absorb excitation light and emitting light having a light emission peak wavelength of 700 nm or more and 1,050 nm or less, which enables measurement of internal information on living bodies and foods such as fruits and vegetables. In the present specification, the term “molar ratio” represents the ratio of each element in 1 mol of the chemical composition of the fluorescent material, unless otherwise specified.

The oxide fluorescent material preferably has a composition included in the compositional formula represented by the following formula (1):

M¹ₜM²ᵤ(Ge₁₋ᵥM³ᵥ)₆O_{w}:Crₓ,M⁴_{y} (1)

wherein t, u, v, w, x, and y each satisfy 1.5≤t≤2.5, 0.7≤u≤1.3, 0≤v≤0.4, 12.9≤w≤15.1, 0<x≤0.2, 0≤y≤0.10,and y<x.

In the oxide fluorescent material, the first element M¹ is at least one element selected from the group consisting of Li, Na, and K, the second element M² contains at least one element selected from the group consisting of Ca and Sr as an essential element and may contain at least one element selected from the group consisting of Mg, Ba, and Zn, the third element M³ may be at least one element selected from the group consisting of Si, Ti, Zr, Sn, Hf, and Pb, and the fourth element M⁴ may be at least one element selected from the group consisting of Yb, Nd, Tm, and Er.

The first element M¹ may be at least one element selected from the group consisting of Li, Na, K, and Rb. The molar ratio of the first element M¹ is 1.5 or more and 2.5 or less, may be 1.7 or more and 2.3 or less, may be 1.8 or more and 2.2 or less, and may be 2, when the molar ratio of Ge, or the total molar ratio of the third element M³ and Ge in the case of including the third element M³, in 1 mol of the composition of the oxide fluorescent material is 6. When the oxide fluorescent material has a composition included in the compositional formula represented by the formula (1), the variable t, which represents the molar ratio of the first element M¹, satisfies 1.5≤t≤2.5, may satisfy 1.7≤t≤2.3, may satisfy 1.8≤t≤2.2, and may satisfy t=2, in 1 mol of the composition of the oxide fluorescent material.

The second element M² may be at least one element selected from the group consisting of Ca and Sr. The molar ratio of the second element M² is 0.7 or more and 1.3 or less, may be 0.8 or more and 1.2 or less, and may be 0.9 or more and 1.1 or less, when the molar ratio of Ge, or the total molar ratio of the third element M³ and Ge in the case of including the third element M³, in 1 mol of the composition of the oxide fluorescent material is 6. When the oxide fluorescent material has a composition included in the compositional formula represented by the formula (1), the variable u, which represents the molar ratio of the second element M², satisfies 0.7≤u≤1.3, may satisfy 0.8≤u≤1.2, and may satisfy 0.9≤u≤1.1, in 1 mol of the composition of the oxide fluorescent material.

The molar ratio of the third element M³ is, in 1 mol of the composition of the oxide fluorescent material, at least one selected from the group consisting of Si, Ti, Zr, Sn, Hf, and Pb, and may contain two or more of these. The molar ratio of the third element M³ is 0 or more and 2.4 or less, may be 0.006 or more and 2.1 or less, may be 0.012 or more and 1.8 or less, and may be 0.030 or more and 1.5 or less, when the molar ratio of Ge, or the total molar ratio of the third element M³ and Ge in the case of including the third element M³, in 1 mol of the composition of the oxide fluorescent material is 6. When the oxide fluorescent material has a composition included in the compositional formula represented by the formula (1), the variable v in the product of the variable v and 6, which represents the molar ratio of the third element M³, may satisfy 0≤v≤0.40, may satisfy 0.001≤v≤0.35, may satisfy 0.002≤v≤0.30, and may satisfy 0.005≤v≤0.25, in 1 mol of the composition of the oxide fluorescent material.

The molar ratio of O (oxygen) contained in the oxide fluorescent material is 12.9 or more and 15.1 or less, may be 13 or more and 15 or less, may be 13.5 or more and 14.5 or less, and may be 14, when the molar ratio of Ge, or the total molar ratio of the third element M³ and Ge in the case of including the third element M³, in 1 mol of the composition of the oxide fluorescent material is 6. When the oxide fluorescent material has a composition included in the compositional formula represented by the formula (1), the variable w, which represents the molar ratio of O (oxygen), satisfies 12.9≤w≤15.1, may satisfy 13.0≤w≤15.0, may satisfy 13.5≤w≤14.5, and may satisfy w=14, in 1 mol of the composition of the oxide fluorescent material.

Cr contained in the oxide fluorescent material is an activating element of the oxide fluorescent material. The molar ratio of Cr contained in the oxide fluorescent material is 0.2 or less when the molar ratio of Ge, or the total molar ratio of the third element M³ and Ge in the case of including the third element M³, in 1 mol of the composition of the oxide fluorescent material is 6. In order for the oxide fluorescent material to emit light by being irradiated with light from an excitation light source such as a light emitting element, the molar ratio of Cr contained in the oxide fluorescent material is a value more than 0, is more than 0 and 0.2 or less, may be 0.001 or more and 0.2 or less, may be 0.002 or more and 0.18 or less, and may be 0.003 or more and 0.15 or less. When the oxide fluorescent material has a composition included in the compositional formula represented by the formula (1), the variable x, which represents the molar ratio of Cr, satisfies 0<x≤0.2, may satisfy 0.001≤x≤0.2, may satisfy 0.002≤x≤0.18, and may satisfy 0.003≤x≤0.15, in 1 mol of the composition of the oxide fluorescent material.

The fourth element M⁴ optionally contained in the oxide fluorescent material is an activating element together with Cr; and may be at least one element selected from the group consisting of Eu, Ce, Tb, Pr, Nd, Sm, Yb, Ho, Er, Tm, Ni, and Mn, and may be at least one element selected from the group consisting of Yb, Nd, Tm, and Er.

As for the molar ratio of the fourth element M⁴ optionally contained in the oxide fluorescent material, when the molar ratio of Ge, or the total molar ratio of the third element M³ and Ge in the case of including the third element M³, in 1 mol of the composition of the oxide fluorescent material is 6, the total molar ratio of Cr and the fourth element M⁴ may be more than 0 and 0.10 or less, may be 0.001 or more and 0.09 or less, and may be 0.002 or more and 0.08 or less. The molar ratio of the fourth element M⁴ is preferably smaller than that of Cr. When the oxide fluorescent material has a composition included in the compositional formula represented by the formula (1), the variable y, which represents the molar ratio of the fourth element M⁴, satisfies 0≤y≤0.10, may satisfy 0.001≤y≤0.10, may satisfy 0.001≤y≤0.09, and may satisfy 0.002≤y≤0.08, in 1 mol of the composition of the oxide fluorescent material. When the oxide fluorescent material has a composition included in the compositional formula represented by the formula (1), the variable x representing the molar ratio of Cr and the variable y representing the molar ratio of the fourth element M⁴ preferably satisfy y<x and 0<x+y≤0.2, in 1 mol of the composition of the oxide fluorescent material.

The oxide fluorescent material preferably has a light emission peak wavelength of 700 nm or more and 1,050 nm or less, and a full width at half maximum of the light emission spectrum having the light emission peak wavelength being 150 nm or more. In the light emission spectrum of the oxide fluorescent material, the full width at half maximum of the light emission spectrum having the light emission peak wavelength is preferably 160 nm or more, more preferably 170 nm or more, and even more preferably 180 nm or more. The oxide fluorescent material preferably has a wider full width at half maximum of the light emission spectrum. The full width at half maximum of the light emission spectrum having the light emission peak wavelength may be 250 nm or less, may be 240 nm or less, may be 230 nm or less, and may be 220 nm or less. In the present specification, the full width at half maximum refers to a width of wavelength, between wavelengths at 50% intensity of the maximum value of emission intensity in the emission spectrum. Light is absorbed and scattered in a living body, and in order to measure a subtle change in propagation behavior of light in the blood in the living body, it is preferable to irradiate light having a light emission peak with a wide full width at half maximum. In the case of measuring foods such as fruits and vegetables in a non-destructive manner, it is also preferable to irradiate light having a light emission peak with a wide full width at half maximum in order to obtain information on the inside of foods. It is also desirable for the color appearance of an object when irradiated with light (hereinafter, also referred to as “color rendering property”) to have a light emission spectrum in a wide wavelength range, and the wider the full width at half maximum, the better the color rendering property of light can be emitted. For example, in the case of emitting light in a wavelength range that affects plant growth in a plant factory, it is sometimes required to emit light that does not disturb the spectral balance of the light in order to facilitate work of workers.

It is preferable that the oxide fluorescent material has a monoclinic crystal structure and belongs to the space group P321. When the oxide fluorescent material has the above-mentioned composition and belongs to the trigonal space group P321, light emission having a light emission peak wavelength of 700 nm or more and 1,050 nm or less can be efficiently obtained by light irradiated from the light emitting element.

### Light Emitting Device

The light emitting device includes an oxide fluorescent material and a light emitting element that irradiates the oxide fluorescent material. The oxide fluorescent material can be used as a member constituting a wavelength conversion member together with a light-transmissive material.

The light emitting device preferably includes a light emitting element that irradiates the oxide fluorescent material, such as an LED chip or an LD chip using a nitride-based semiconductor.

The light emitting element preferably has a light emission peak wavelength of 360 nm or more and 700 nm or less, more preferably 365 nm or more and 600 nm or less, and even more preferably 365 nm or more and 500 nm or less. By using the light emitting element as an excitation light source of the oxide fluorescent material, a light emitting device configured to emit mixed color light of light emitted from the light emitting element and fluorescence emitted from a fluorescent material containing the oxide fluorescent material in a desired wavelength range can be constituted. The full width at half maximum of the light emission peak in the light emission spectrum of the light emitting device can be, for example, 30 nm or less. As the light emitting element, for example, it is preferable to use a light emitting element using a nitride-based semiconductor. By using the light emitting element using a nitride-based semiconductor as an excitation light source, a stable light emitting device having high efficiency, high output linearity with respect to input, and high resistance to mechanical impacts can be obtained.

The light emitting device essentially includes a first fluorescent material containing the above-mentioned oxide fluorescent material, and may further include other different fluorescent materials. The light emitting device preferably includes, in addition to the first fluorescent material, at least one fluorescent material selected from the group consisting of a second fluorescent material having a light emission peak wavelength of 455 nm or more and less than 495 nm, a third fluorescent material having a light emission peak wavelength of 495 nm or more and less than 610 nm, a fourth fluorescent material having a light emission peak wavelength of 610 nm or more and less than 700 nm, and a fifth fluorescent material having a light emission peak wavelength of 700 nm or more and 1,050 nm or less, in the light emission spectrum of each fluorescent material. The light emitting device preferably has a light emission spectrum that is continuous in a range equal to or greater than the light emission peak wavelength of the light emitting element and equal to or less than 1,050 nm, in which when the maximum value of the light emission intensity in the range in a range equal to or greater than the light emission peak wavelength of the light emitting element and equal to or less than 1,050 nm is 100%, the minimum value of the light emission intensity in the range in a range equal to or greater than the light emission peak wavelength of the light emitting element and equal to or less than 1,050 nm is 10% or more. The expression “light emission spectrum of the light emitting device is continuous in the range equal to or greater than the light emission peak wavelength of the light emitting element and equal to or less than 1,050 nm or less” means that the light emission intensity of the light emission spectrum does not become 0% and the light emission spectrum is continuous without interruption within the entire wavelength range equal to or greater than the light emission peak wavelength of the light emitting element and equal to or less than 1,050 nm. Depending on the measurement target or detection target such as in a living body or fruits and vegetables, a light source that emits light having a continuous light emission spectrum in a wavelength range including visible light to a part of near-infrared light may be required. In the case of using a tungsten lamp or a xenon lamp as the light source, light having a continuous light emission spectrum may be emitted without interrupting the light emission spectrum in the wavelength range including visible light to a part of near-infrared light. However, when using a tungsten lamp or a xenon lamp as the light source, it may be difficult to miniaturize the device. The light emitting device configured to emit light having a light emission spectrum that is continuous in a range equal to or greater than the light emission peak wavelength of the light emitting element and equal to or less than 1,050 nm or less, in which when the maximum value of the light emission intensity in the range equal to or greater than the light emission peak wavelength of the light emitting element and equal to or less than 1,050 nm or less is 100%, the minimum value of the light emission intensity in the range equal to or greater than the light emission peak wavelength of the light emitting element and equal to or less than 1,050 nm or less is 10% or more, can be reduced in size compared to light emitting devices using a tungsten lamp or a xenon lamp as the light source. A small light emitting device can be mounted on a small mobile device such as a smartphone to obtain information in a living body, which can be used to manage physical conditions. As used herein, the term “within the range equal to or greater than the light emission peak wavelength of the light emitting element and equal to or less than 1,050 nm ” refers to, for example, 420 nm or more and 1,050 nm or less when the light emission peak wavelength of the light emitting element is 420 nm.

The light emitting device has a light emission spectrum that is continuous in a range equal to or greater than the light emission peak wavelength of the light emitting element and equal to or less than 1,050 nm, in which when the maximum value of the light emission intensity in the range equal to or greater than the light emission peak wavelength of the light emitting element and equal to or less than 1,050 nm is 100%, the minimum value of the light emission intensity in the range equal to or greater than the light emission peak wavelength of the light emitting element and equal to or less than 1,050 nm is 10% or more, thereby emitting light in a wide wavelength range from visible light to near-infrared light. Such a light emitting device can be used, for example, in a reflection spectroscopic measuring device, and a lighting device capable of non-destructively measuring a living body, fruits and vegetables, and the like and emitting light having a good color rendering property.

The second fluorescent material, which has a composition different from that of the first fluorescent material containing the above-mentioned oxide fluorescent material, preferably contains at least one fluorescent material selected from the group consisting of a phosphate fluorescent material having a composition included in a compositional formula represented by the following formula (2a), an aluminate fluorescent material having a composition included in a compositional formula represented by the following formula (2b), and an aluminate fluorescent material having a composition represented by the following formula (2c); and may contain two or more fluorescent materials of these.

(Ca,Sr,Ba,Mg)₁₀(PO₄)₆(F,Cl,Br,I)₂:Eu (2a),

(Ba,Sr,Ca)MgAl₁₀O₁₇:Eu (2b), and

Sr₄Al₁₄O₂₅:EU (2c).

In the present specification, plural elements sectioned by comma (,) in the compositional formulae mean that at least one of these plural elements is contained in the composition. In the present specification, in the compositional formulae representing the compositions of the fluorescent materials, the part before the colon (:) represents elements and the molar ratio constituting a host crystal, and the part after the colon (:) represents an activating element.

The third fluorescent material preferably contains at least one fluorescent material selected from the group consisting of a silicate fluorescent material having a composition included in a compositional formula represented by the following formula (3a), an aluminate fluorescent material or a gallate fluorescent material having a composition included in a compositional formula represented by the following formula (3b), a β-SiAlON fluorescent material having a composition included in a compositional formula represented by the following formula (3c), a cesium lead halide fluorescent material having a composition included in a compositional formula represented by the following formula (3d), and a nitride fluorescent material having a composition included in a compositional formula represented by the following formula (3e); and may contain two or more fluorescent materials of these. In the case where the third fluorescent material contains two or more fluorescent materials, the two or more fluorescent materials preferably has their respective light emission peak wavelengths in respective ranges different from each other within a range equal to or greater than 495 nm and less than 610 nm.

(Ca,Sr,Ba)₈MgSi₄O₁₆(F,Cl,Br)₂:Eu (3a),

(Lu,Y,Gd,Tb)₃(Al,Ga)₅O₁₂:Ce (3b),

Si_{6-z}Al_{z}O_{z}N_{8-z}:Eu (0<z≤4.2) (3c),

CsPb(F,Cl,Br)₃ (3d), and

(La,Y,Gd)₃Si₆N₁₁:Ce (3e).

The fourth fluorescent material preferably contains at least one fluorescent material selected from the group consisting of a nitride fluorescent material having a composition included in a compositional formula represented by the following formula (4a), a fluoro-germanate fluorescent material having a composition represented by the following formula (4b), an oxynitride fluorescent material having a composition included in a compositional formula represented by the following formula (4c), a fluoride fluorescent material having a composition included in a compositional formula represented by the following formula (4d), a fluoride fluorescent material having a composition included in a compositional formula represented by the following formula (4e), a nitride fluorescent material having a composition included in a compositional formula represented by the following formula (4f), and a nitride fluorescent material having a composition included in a compositional formula represented by the following formula (4g); and may contain two or more fluorescent materials of these. In the case where the fourth fluorescent material contains two or more fluorescent materials, the two or more fluorescent materials preferably have their respective light emission peak wavelengths in ranges different from each other within a range equal to or greater than 610 nm and less than 700 nm.

(Sr,Ca)AlSiN₃:Eu (4a),

3.5MgO·0.5MgF₂·GeO₂:Mn (4b),

(Ca,Sr,Mg)ₖSi₁₂₋₍ₘ₊ₙ₎Alₘ₊ₙOₙN₁₆₋ₙ:Eu (4c),

wherein k, m, and n each satisfy 0<k≤2.0, 2.0≤m≤6.0, and 0≤n≤2.0,

A_{c}[M⁶_{1-b}Mn⁴⁺_{b}F_{d}] (4d),

wherein A includes at least one selected from the group consisting of K⁺, Li⁺, Na⁺, Rb⁺, Cs⁺, and NH₄⁺; M⁶ includes at least one element selected from the group consisting of Group 4 elements and Group 14 elements, of which Si and Ge are preferred; b satisfies 0<b<0.2; c represents the absolute value of the charge of [M⁶_{1-b}Mn⁴⁺_{b}F_{d}]ions; and d satisfies 5<d<7,

A′_{c′}[M^{6′}_{1-b′}Mn⁴⁺_{b′}F_{d′}] (4e),

wherein A′ includes at least one selected from the group consisting of K⁺, Li⁺, Na⁺, Rb⁺, Cs⁺, and NH₄⁺; M^{6′} includes at least one element selected from the group consisting of Group 4 elements, Group 13 elements, and Group 14 elements, of which Si and Al are preferred; b′ satisfies 0<b′<0.2; c′ represents the absolute value of the charge of [M^{6′}_{1-b′}Mn⁴⁺_{b′}F_{d′}] ions; and d′ satisfies 5<d′<7,

(Ba,Sr,Ca)₂Si₅N₈:Eu (4f), and

(Sr,Ca)LiAl₃N₄:Eu (4g).

The fifth fluorescent material preferably contains at least one fluorescent material selected from the group consisting of a gallate fluorescent material having a composition represented by the following formula (5a), an aluminate fluorescent material having a composition represented by the following formula (5b), a gallate fluorescent material having a composition represented by the following formula (5c), an aluminate fluorescent material having a composition included in a compositional formula represented by the following formula (5d), and a fluorescent material having a composition included in a compositional formula represented by the following formula (5e), which is different from the composition of the above-mentioned oxide fluorescent material; and may contain two or more fluorescent materials of these.

Ga₂O₃:Cr (5a),

Al₂O₃:Cr (5b),

ZnGa₂O₄:Cr (5c),

(Lu,Y,Gd,Tb)₃(Al,Ga)₅O₁₂:Ce,Cr (5d), and

M⁷_{g}M⁸ₕM⁹ᵢM¹⁰₅Oⱼ:Crₑ,M¹¹_{f} (5e),

wherein M⁷ includes at least one element selected from the group consisting of Li, Na, Ka, Rb, and Cs; M⁸ includes at least one element selected from the group consisting of Mg, Ca, Sr, Ba, and Zn; M⁹ includes at least one element selected from the group consisting of Ba, Al, Ga, In and rare earth elements; M¹⁰ includes at least one element selected from the group consisting of Si, Ti, Ge, Zr, Sn, Hf, and Pb; Mu includes at least one element selected from the group consisting of Eu, Ce, Tb, Pr, Nd, Sm, Yb, Ho, Er, Tm, Ni, and Mn; and e, f, g, h, i, and j each satisfy 0<e≤0.2, 0≤f≤0.1, f≤e, 0.7≤g≤1.3, 1.5≤h≤2.5, 0.7≤i≤1.3, and 12.9≤j≤15.1.

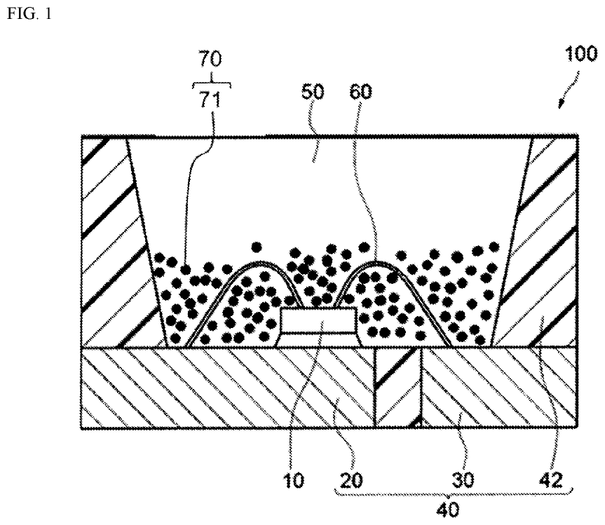

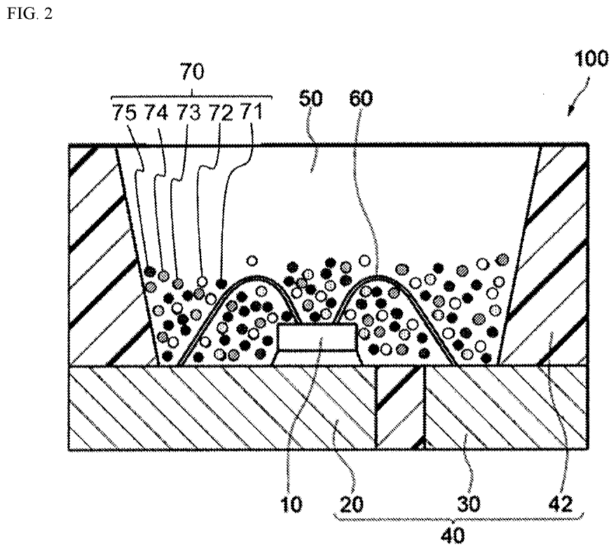

An example of the light emitting device will be described with reference to the drawings. FIG. 1 is a schematic cross-sectional view showing an exemplary light emitting device according to a first embodiment of the present disclosure. FIG. 2 is a schematic cross-sectional view showing another exemplary light emitting device according to the first embodiment of the present disclosure.

As shown in FIG. 1, a light emitting device 100 is provided with a molded body 40 having a recessed portion, a light emitting element 10 serving as an excitation light source, and a wavelength conversion member 50 that covers the light emitting element 10. The molded body 40 is formed by integrally molding a first lead 20, a second lead 30, and a resin portion 42 containing a thermoplastic resin or a thermosetting resin. In the molded body 40, the first lead 20 and the second lead 30 constituting the bottom surface of the recessed portion are arranged, and the resin portion 42 constituting the side surfaces of the recessed portion is arranged. The light emitting element 10 is mounted on the bottom surface of the recessed portion of the molded body 40. The light emitting element 10 has a pair of positive and negative electrodes, and the pair of positive and negative electrodes each are electrically connected to the first lead 20 and the second lead 30 via a wire 60. The light emitting element 10 is covered by the wavelength conversion member 50. The wavelength conversion member 50 contains a fluorescent material 70 that converts the wavelength of light emitted from the light emitting element 10 and a light-transmissive material. The fluorescent material 70 contains a first fluorescent material 71 containing an oxide fluorescent material. The fluorescent material 70 may contain a fluorescent material having a light emission peak wavelength in a wavelength range different from that of the first fluorescent material 71. As shown in FIG. 2, the fluorescent material 70 preferably contains at least one fluorescent material selected from the group consisting of the second fluorescent material 72, the third fluorescent material 73, the fourth fluorescent material 74, and the fifth fluorescent material 75 described above, and may contain two or more types of these. The fluorescent material 70 essentially contains the first fluorescent material 71, and may contain the second fluorescent material 72, the third fluorescent material 73, the fourth fluorescent material 74, and the fifth fluorescent material 75. The wavelength conversion member 50 also functions as a member for protecting the light emitting element 10 and the fluorescent material 70 from the external environment. The light emitting device 100 emits light upon receiving external electric power via the first lead 20 and the second lead 30.

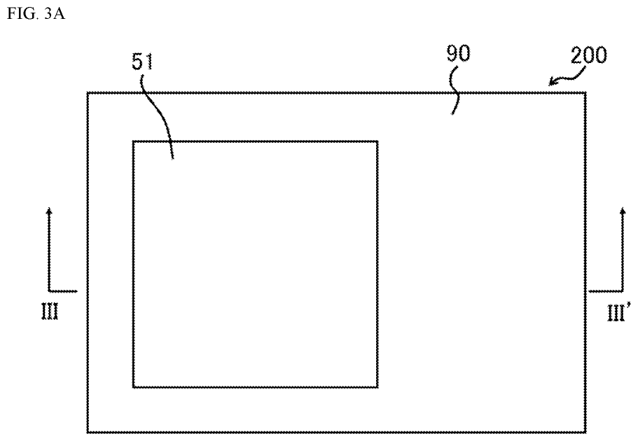

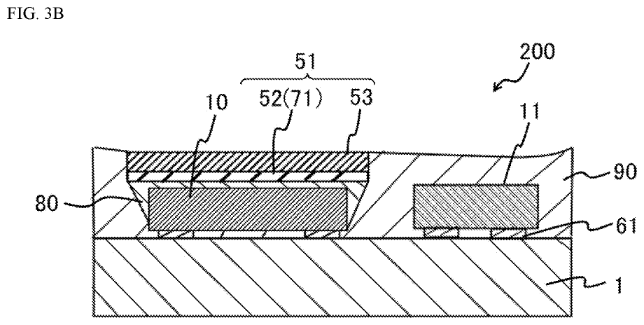

FIGS. 3A and 3B show an exemplary light emitting device according to a second embodiment of the present disclosure. FIG. 3A is a schematic plan view of a light emitting device 200. FIG. 3B is a schematic cross-sectional view of the III-III′ line of the light emitting device 200 shown in FIG. 3A. The light emitting device 200 includes a light emitting element 10 having a light emission peak wavelength of 365 nm or more and 500 nm or less, and a wavelength conversion member 51 including a wavelength conversion body 52 containing a first fluorescent material 71 that is excited by light emitted from the light emitting element 10 and emits light, and a light-transmissive body 53 on which the wavelength conversion body 52 is arranged. The light emitting element 10 is flip-chip mounted on a substrate 1 via bumps that are conductive members 61. The wavelength conversion body 52 of the wavelength conversion member 51 is arranged on the light emitting surface of the light emitting element 10 via an adhesive layer 80. The side surfaces of the light emitting element 10 and the wavelength conversion member 52 are covered with a covering member 90 that reflects light. The wavelength conversion body 52 is excited by light emitted from the light emitting element 10 and essentially contains the first fluorescent material 71 containing an oxide fluorescent material. The wavelength conversion body 52 may contain at least one selected from the group consisting of the second fluorescent material, the third fluorescent material, the fourth fluorescent material, and the fifth fluorescent material. The light emitting element 10 receives electric power from the outside of the light emitting device 200 via the wiring and the conductive members 61 formed on the substrate 1, thereby allowing the light emitting device 200 to emit light. The light emitting device 200 may include a semiconductor element 11 such as a protective element for preventing the light emitting element 10 from being destroyed due to excessive voltage application. The covering member 90 is provided so as to cover, for example, the semiconductor element 11. Each member used in the light emitting device will be hereunder described. For the details, for example, the disclosure of Japanese Unexamined Patent Publication No. 2014-112635 may be referred to.

Examples of the light-transmissive material constituting the wavelength conversion member together with the fluorescent material include at least one selected from the group consisting of resin, glass, and inorganic substances. The resin can use at least one resin selected from the group consisting of a silicone resin, an epoxy resin, a phenol resin, a polycarbonate resin, an acrylic resin, and modified resins thereof. Among these, a silicone resin and a modified silicone resin are preferred because they have good heat resistance and light resistance. The wavelength conversion member may optionally contain a filler, a colorant, and a light diffusing material in addition to the fluorescent material and the light-transmissive material. Examples of the filler include silicon oxide, barium titanate, titanium oxide, and aluminum oxide.

When the wavelength conversion member includes a resin and a fluorescent material, it is preferable to form a wavelength conversion member-forming composition that includes the fluorescent material in the resin, and then form a wavelength conversion member using the wavelength conversion member-forming composition. In the wavelength conversion member-forming composition, the content of the first fluorescent material containing an oxide fluorescent material is preferably 20 parts by mass or more and 100 parts by mass or less, may be 25 parts by mass or more and 90 parts by mass or less, and may be 30 parts by mass or more and 85 parts by mass or less, relative to 100 parts by mass of the resin. The first fluorescent material may contain only an oxide fluorescent material. The oxide fluorescent material contained in the first fluorescent material may include two or more types of oxide fluorescent materials having different compositions.

The content of each fluorescent material in the wavelength conversion member-forming composition is within the range described below.

The content of the second fluorescent material contained in the wavelength conversion member-forming composition may be 10 parts by mass or more and 100 parts by mass or less, may be 20 parts by mass or more and 90 parts by mass or less, and may be 30 parts by mass or more and 80 parts by mass or less, relative to 100 parts by mass of the resin.

The content of the third fluorescent material contained in the wavelength conversion member-forming composition may be 5 parts by mass or more and 100 parts by mass or less, may be 10 parts by mass or more and 90 parts by mass or less, may be 15 parts by mass or more and 80 parts by mass or less, may be 20 parts by mass or more and 70 parts by mass or less, and may be 25 parts by mass or more and 60 parts by mass or less, relative to 100 parts by mass of the resin.

The content of the fourth fluorescent material contained in the wavelength conversion member-forming composition may be 1 part by mass or more and 50 parts by mass or less, may be 2 parts by mass or more and 40 parts by mass or less, may be 3 parts by mass or more and 30 parts by mass or less, may be 4 parts by mass or more and 40 parts by mass or less, and may be 5 parts by mass or more and 20 parts by mass or less, relative to 100 parts by mass of the resin.

The content of the fifth fluorescent material contained in the wavelength conversion member-forming composition may be 5 parts by mass or more and 100 parts by mass or less, may be 10 parts by mass or more and 90 parts by mass or less, may be 10 parts by mass or more and 80 parts by mass or less, and may be 15 parts by mass or more and 70 parts by mass or less, relative to 100 parts by mass of the resin. When the wavelength conversion member-forming composition contains a fifth fluorescent material and the fifth fluorescent material contains two or more types of fluorescent materials, the content of the fifth fluorescent material refers to the total content of the two or more types of the fifth fluorescent materials. When the wavelength conversion member-forming composition contains two or more types of fluorescent materials of any of the second to fourth fluorescent materials, the content thereof refers to the total content of the two or more types of the fluorescent materials.

The total content of the fluorescent materials contained in the wavelength conversion member-forming composition may be 50 parts by mass or more and 300 parts by mass or less, may be 100 parts by mass or more and 280 parts by mass or less, may be 120 parts by mass or more and 250 parts by mass or less, and may be 150 parts by mass or more and 200 parts by mass or less, relative to 100 parts by mass of the resin.

The wavelength conversion member may include a light-transmissive body. The light-transmissive body can use a plate-shaped body made of a light-transmissive material such as glass or resin. Examples of the glass include borosilicate glass and quartz glass. Examples of the resin include a silicone resin and an epoxy resin. When the wavelength conversion member includes a substrate, the substrate is preferably made of an insulating material that is difficult to transmit light from the light emitting element and external light. Examples of the material of the substrate include ceramics such as aluminum oxide and aluminum nitride, and resins such as a phenol resin, an epoxy resin, a polyimide resin, a bismaleimide triazine resin (BT resin), and a polyphthalamide (PPA) resin. When an adhesive layer is interposed between the light emitting element and the wavelength conversion member, the adhesive constituting the adhesive layer is preferably made of a material capable of optically connecting the light emitting element and the wavelength conversion member. The material constituting the adhesive layer is preferably at least one resin selected from the group consisting of an epoxy resin, a silicone resin, a phenol resin, and a polyimide resin.

Examples of the semiconductor element optionally provided in the light emitting device include a transistor for controlling the light emitting element and a protective element for suppressing the destruction and the performance deterioration of the light emitting element due to excessive voltage application. Examples of the protective element include a Zener diode. When the light emitting device includes a covering member, it is preferable to use an insulating material as the material of the covering member. More specific examples thereof include a phenol resin, an epoxy resin, a bismaleimide triazine resin (BT resin), a polyphthalamide (PPA) resin, and a silicone resin. The covering member may be optionally added with a colorant, a fluorescent material, and a filler. The light emitting device may use bumps as conductive members. Examples of the material of the bumps include Au and an alloy thereof, and examples of the other conductive member include eutectic solder (Au—Sn), Pb—Sn, and lead-free solder.

### Method for Producing Light Emitting Device

An example of the method for producing an exemplary light emitting device according to the first embodiment will be described. For the details, for example, the disclosure of Japanese Unexamined Patent Publication No. 2010-062272 may be referred to. The method for producing a light emitting device preferably includes a step of preparing a molded body, a step of arranging a light emitting element, a step of arranging a wavelength conversion member-forming composition, and a step of forming a resin package. When using a collective molded body having a plurality of recessed portions as the molded body, the production method may include, after the step of forming a resin package, a singulating step of separating into individual resin packages for respective unit regions.

In the step of preparing a molded body, a plurality of leads are integrally molded with a thermosetting resin or a thermoplastic resin to prepare a molded body having a recessed portion with side surfaces and a bottom surface. The molded body may be formed from a collective substrate including a plurality of recessed portions.

In the step of arranging a light emitting element, a light emitting element is arranged on the bottom surface of the recessed portion of the molded body, and positive and negative electrodes of the light emitting element are connected to a first lead and a second lead, respectively, by a wire.

In the step of arranging a wavelength conversion member-forming composition, the wavelength conversion member-forming composition is arranged in the recessed portion of the molded body.

In the step of forming a resin package, the wavelength conversion member-forming composition arranged in the recessed portion of the molded body is cured to form a resin package, thereby producing a light emitting device. When using a molded body formed from a collective substrate having a plurality of recessed portions, in the singulation step after the step of forming a resin package, the collective substrate is separated into individual resin package for respective unit regions of the collective substrate having a plurality of recessed portions, thereby producing individual light emitting devices. As described above, the light emitting devices shown in FIGS. 1 and 2 can be produced.

An example of the method for producing an exemplary light emitting device according to the second embodiment will be described. For the details, for example, the disclosure of Japanese Unexamined Patent Publication No. 2014-112635 or Japanese Unexamined Patent Publication No. 2017-117912 may be referred to. The method for producing a light emitting device preferably includes a step of arranging a light emitting element, optionally a step of arranging a semiconductor element, a step of forming a wavelength conversion member including a wavelength conversion body, a step of adhering a light emitting element and a wavelength conversion member, and a step of forming a covering member.

For example, in the step of arranging a light emitting element, the light emitting element is arranged on the substrate. For example, the light emitting element and the semiconductor element are flip-chip mounted on the substrate. Next, in the step of forming a wavelength conversion member including a wavelength conversion body, the wavelength conversion body may be obtained by forming a plate-shaped, sheet-shaped, or layered wavelength conversion body on one surface of the light-transmissive body by a printing method, an adhesive method, a compression molding method, or an electrodeposition method. For example, in the printing method, the composition for a wavelength conversion body containing a fluorescent material and a resin serving as a binder or a solvent can be printed on one surface of the light-transmissive body to form a wavelength converter member including a wavelength conversion body. Next, in the step of adhering a light emitting element and a wavelength conversion member, the wavelength conversion member is opposed to the light emitting surface of the light emitting element, and the wavelength conversion member is adhered onto the light emitting element by the adhesive layer. Next, in the step of forming a covering member, the side surfaces of the light emitting element and the wavelength conversion member are covered with the composition for a covering member. The covering member is for reflecting light emitted from the light emitting element, and when the light emitting device also includes a semiconductor element, it is preferable to form the covering member such that the semiconductor element is embedded by the covering member. As described above, the light emitting device shown in FIGS. 3A and 3B can be produced.

### Method for Producing Oxide Fluorescent Material

The method for producing an oxide fluorescent material includes: preparing a first compound containing a first element M¹ being at least one element selected from the group consisting of Li, Na, K, Rb, and Cs, a second compound containing a second element M² being at least one element selected from the group consisting of Ca, Sr, Mg, Ba, and Zn, a fifth compound containing Ge, a sixth compound containing Cr, optionally a third compound containing a third element M³ being at least one element selected from the group consisting of Si, Ti, Ge, Zr, Sn, Hf, and Pb, and optionally a fourth compound containing a fourth element M⁴ being at least one element selected from the group consisting of Eu, Ce, Tb, Pr, Nd, Sm, Yb, Ho, Er, Tm, Ni, and Mn; adjusting and mixing the first compound, the second compound, the fifth compound, the sixth compound, and optionally the third compound or the fourth compound to prepare a raw material mixture such that, when the molar ratio of Ge, or the total molar ratio of the third element M³ and Ge in the case of including the third element M³, in 1 mol of the composition of the oxide fluorescent material is 6, the molar ratio of the first element M¹ is 1.5 or more and 2.5 or less, the molar ratio of the second element M² is 0.7 or more and 1.3 or less, and the molar ratio of Cr is 0.2 or less; and heat-treating the raw material mixture at a temperature of 900° C. or higher and 1,200° C. or lower in an atmosphere containing oxygen to obtain an oxide fluorescent material, wherein at least one selected from the group consisting of the first compound, the second compound, the fifth compound, and the sixth compound uses an oxide.

### Step of Preparing Raw Material Mixture

### Raw Materials

The raw materials for producing an oxide fluorescent material include a first compound containing a first element M¹, a second compound containing a second element M², a fifth compound containing Ge, and a sixth compound containing Cr. Examples of the first compound, the second compound, the fifth compound, and the sixth compound include oxides, carbonates, and chlorides, and hydrates of these. At least one compound selected from the group consisting of the first compound, the second compound, the fifth compound, and the sixth compound is an oxide, and two or more compounds may be oxides. A third compound containing a third element M³ or a fourth compound containing a fourth element M⁴, which is optionally contained, may be an oxide. The first compound, the second compound, the third compound, the fourth compound, the fifth compound, and the sixth compound are preferably in the form of powder.

Specific examples of the first compound include Li₂O, Li₂CO₃, LiCl, Na₂O, Na₂CO₃, NaCl, K₂O, K₂CO₃, KCl, Rb₂O, Rb₂CO₃, RbCl, Cs₂O, Cs₂CO₃, and CsCl. Specific examples of the second compound include CaO, CaCO₃, CaCl₂, SrO, SrCO₃, SrCl₂, MgO, MgCO₃, MgCl₂, BaO, BaCO₃, BaCl₂, ZnO, and ZnCl₂.

Examples of the third compound containing a third element M³ include oxides and chlorides, and hydrates of these. The third compound is preferably in the form of powder. Specific examples of the third compound include SiO₂, TiO₂, TiCl₄, ZrO₂, ZrCl₄, SnO₂, SnCl₂, HfO₂, HfCl₄, PbO, and Pb₃O₄. The third compound may be a hydrate.

Examples of the fourth compound containing a fourth element M⁴ include oxides, carbonates, and chlorides, and hydrates of these. The fourth compound may be an oxide. The fourth compound is preferably in the form of powder. Specific examples of the fourth compound include Eu₂O₃, EuCl₃, CeO₂, Ce₂O₃, Ce₂(CO₃)₃, Tb₄O₇, TbCl₃, Pr₆O₁₁, PrCl₃, Nd₂(CO₃)₃, Nd₂O₃, NdCl₃, Sm₂(CO₃)₃, Sm₂O₃, SmCl₃, Yb₂O₃, YbCl₃, Ho₂O₃, HoCl₃, Er₂O₃, ErCl₃, Tm₂O₃, TmCl₃, NiO, NiCl₂, MnO, MnO₂, Mn₂O₃, and Mn₃O₄. These compounds may be hydrates.

Specific examples of the fifth compound include GeO₂ and GeCl₄. Specific examples of the sixth compound include Cr₂O₃, Cr₂(CO₃)₃, and CrCl₃. The first compound, the second compound, the fifth compound, and the sixth compound may be hydrates.

### Raw Material Mixture

For each compound to be used as a raw material, the first compound, the second compound, the fifth compound, and the sixth compound are weighed such that, when the molar ratio of Ge, or the total molar ratio of the third element M³ and Ge in the case of including the third element M³, in 1 mol of the composition of the oxide fluorescent material to be obtained is 6, the molar ratio of the first element M¹ is, for example, 2, the molar ratio of the second element M² is, for example, 1, and the molar ratio of Cr is 0.2 or less; and each compound is mixed to obtain a raw material mixture. In the case where the third compound is contained as a raw material, the third compound may be weighed such that, when the molar ratio of the third element M³ in 1 mol of the composition of the oxide fluorescent material to be obtained is represented by the product of a variable v and 6, the variable v is 0.4 mol or less, and each compound may be mixed to obtain a raw material mixture. In the case where the fourth compound is contained as a raw material, the fourth compound may be weighed such that the molar ratio of the fourth element M⁴ in 1 mol of the composition of the oxide fluorescent material to be obtained is 0.10 or less, and each compound may be mixed to obtain a raw material mixture. The weighed first compound, second compound, fifth compound, and sixth compound, as well as the third compound or fourth compound optionally contained are mixed in wet or in dry to obtain a raw material mixture. The weighed compounds may be mixed using a mixing machine. As the mixing machine, a ball mill, a vibration mill, a roll mill, a jet mill, and the like, which are industrially commonly used, can be used.

For each compound to be used as a raw material, it is preferable to prepare a raw material mixture by weighing and mixing each compound such that the first element M¹, the second element M², Ge, and Cr contained in each compound, as well as the third element M³ or the fourth element M⁴ optionally contained, satisfy a composition included in a compositional formula represented by the above-mentioned formula (1).

### Flux

The raw material mixture may contain a flux. When the raw material mixture contains a flux, the reaction among the raw materials is more promoted and the solid-phase reaction proceeds more uniformly, so that a fluorescent material having a large particle diameter and excellent light emission characteristics can be obtained. When the temperature of the heat treatment for obtaining a fluorescent material is similar to the temperature at which the liquid phase of the compound used as the flux is formed, the flux promotes the reaction among the raw materials. As the flux, a halide containing at least one element selected from the group consisting of rare earth elements, alkaline earth metal elements, and alkali metal elements can be used. Among the halides, fluoride can be used as the flux. In the case where the element contained in the flux is the same as the at least a part of the elements constituting the oxide fluorescent material, the flux can be added as part of the raw materials of the oxide fluorescent material having the desired composition such that the composition of the oxide fluorescent material has the desired composition, or the flux can be added as a further addition after mixing the raw materials to achieve the desired composition.

### Step of Heat-Treating to Obtain Oxide Fluorescent Material

The raw material mixture can be placed in a crucible or a boat made of a material such as graphite or other carbon, boron nitride (BN), alumina (Al₂O₃), tungsten (W), or molybdenum (Mo), and heat-treated in a furnace.

### Heat Treatment Atmosphere

The heat treatment is preferably carried out in an atmosphere containing oxygen. Any appropriate content of oxygen can be contained in the atmosphere. The content of oxygen in the atmosphere containing oxygen is preferably 5% by volume or more, more preferably 10% by volume or more, and even more preferably 15% by volume or more. The heat treatment is preferably carried out in an air atmosphere (oxygen content of 20% by volume or more). When the atmosphere does not contain oxygen, such as an oxygen content of less than 1% by volume, an oxide fluorescent material having the desired composition may not be obtained.

### Heat Treatment Temperature

The heat treatment temperature is 900° C. or higher and 1,500° C. or lower, preferably 950° C. or higher and 1,400° C. or lower, and more preferably 1,000° C. or higher and 1,200° C. or lower. When the heat treatment temperature is 900° C. or higher and 1,500° C. or lower, decomposition due to heat is suppressed, so that a fluorescent material having the desired composition and a stable crystal structure can be obtained.

In the heat treatment, a maintaining time at a predetermined temperature may be set. The maintaining time may be, for example, 0.5 hour or more and 48 hours or less, may be 1 hour or more and 40 hours or less, and may be 2 hours or more and 30 hours or less. By setting the maintaining time in the range of 0.5 hour or more and 48 hours or less, the crystal growth can be promoted.

The pressure in the heat treatment atmosphere may be standard atmospheric pressure (0.101 MPa), and may be 0.101 MPa or more; and the heat treatment is preferably carried out in a pressurized atmosphere range of 0.11 MPa or more and 200 MPa or less. Although the crystal structure of a heat-treated product to be obtained by the heat treatment tends to be decomposed when the heat treatment temperature is high, the decomposition of the crystal structure can be impeded in a pressurized atmosphere.

The heat treatment time can be appropriately selected depending on the heat treatment temperature and the pressure of the atmosphere during the heat treatment, and is preferably 0.5 hour or more and 20 hours or less. Even in the case of carrying out two or more stages of heat treatment, the time for one heat treatment is preferably 0.5 hour or more and 20 hours or less. When the heat treatment time falls within the range of 0.5 hour or more and 20 hours or less, the decomposition of a heat-treated product to be obtained is suppressed, and a fluorescent material having a stable crystal structure and the desired light emission intensity can be obtained. In addition, the production cost can be reduced and the production time can be relatively shortened. The heat treatment time is more preferably 1 hour or more and 10 hours or less, and even more preferably 1.5 hours or more and 9 hours or less.

The heat-treated product obtained by the heat treatment may be subjected to post-treatments such as pulverization, dispersion, solid-liquid separation, and drying. The solid-liquid separation may be carried out by a method generally used industrially, such as filtration, suction filtration, pressure filtration, centrifugal separation, and decantation. The drying may be carried out with an apparatus generally used industrially, such as a vacuum dryer, a hot air dryer, a conical dryer, and a rotary evaporator.

### EXAMPLES

The present disclosure is hereunder specifically described by reference to the following Examples. The present disclosure is not limited to these Examples.

### Oxide Fluorescent Material

### Example 1

Raw materials weighed so as to be 5.30 g of Na₂CO₃, 7.39 g of SrCO₃, 31.40 g of GeO₂, and 0.30 g of Cr₂O₃ were used. Each element in 1 mol of the composition of the oxide fluorescent material to be obtained was weighed such that the molar ratio of each element in the charged composition was Na₂SrGe₆O₁₄:Cr_{0.03}. In the charged composition, the molar ratio of the element for which the molar ratio was not described was 1. Using an agate mortar and an agate pestle, the raw materials were mixed for 10 minutes to obtain a raw material mixture. The resulting raw material mixture was placed in an alumina crucible and heat-treated at 1,050° C. for 8 hours in an air atmosphere (20% by volume of oxygen) with standard air pressure (0.101 MPa). After the heat treatment, the resulting heat-treated product was pulverized to obtain an oxide fluorescent material of Example 1.

### Example 2

Raw materials weighed so as to be 5.30 g of Na₂CO₃, 5.02 g of CaCO₃, 31.40 g of GeO₂, and 0.30 g of Cr₂O₃ were used. An oxide fluorescent material of Example 2 was obtained in the same manner as in Example 1 except that each element in 1 mol of the composition of the oxide fluorescent material to be obtained was weighed such that the molar ratio of each element in the charged composition was Na₂CaGe₆O₁₄:Cr_{0.03}.

### Example 3

Raw materials weighed so as to be 6.91 g of K₂CO₃, 7.39 g of SrCO₃, 31.40 g of GeO₂, and 0.30 g of Cr₂O₃ were used. An oxide fluorescent material of Example 3 was obtained in the same manner as in Example 1 except that each element in 1 mol of the composition of the oxide fluorescent material to be obtained was weighed such that the molar ratio of each element in the charged composition was K₂SrGe₆O₁₄:Cr_{0.03}.

### Example 4

Raw materials weighed so as to be 3.70 g of Li₂CO₃, 5.02 g of CaCO₃, 31.40 g of GeO₂, and 0.30 g of Cr₂O₃ were used. An oxide fluorescent material of Example 4 was obtained in the same manner as in Example 1 except that each element in 1 mol of the composition of the oxide fluorescent material to be obtained was weighed such that the molar ratio of each element in the charged composition was Li₂CaGe₆O₁₄:Cr_{0.03}.

### Comparative Example 1

Raw materials weighed so as to be 5.30 g of Na₂CO₃, 5.02 g of CaCO₃, 18.03 g of SiO₂, and 0.30 g of Cr₂O₃ were used. An oxide of Comparative Example 1 was obtained in the same manner as in Example 1 except that each element in 1 mol of the composition of the oxide fluorescent material to be obtained was weighed such that the molar ratio of each element in the charged composition was Na₂CaSi₆O₁₄:Cr_{0.03}.

### Measurement of Light Emission Spectrum and Light Emission Characteristics

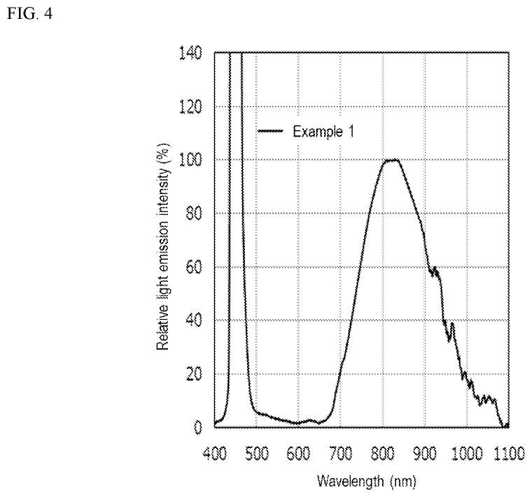

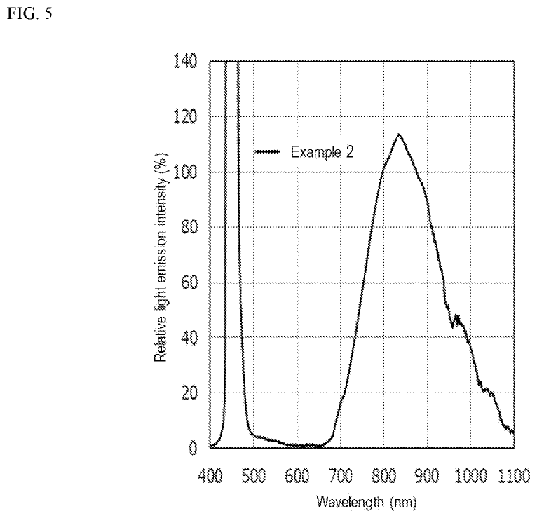

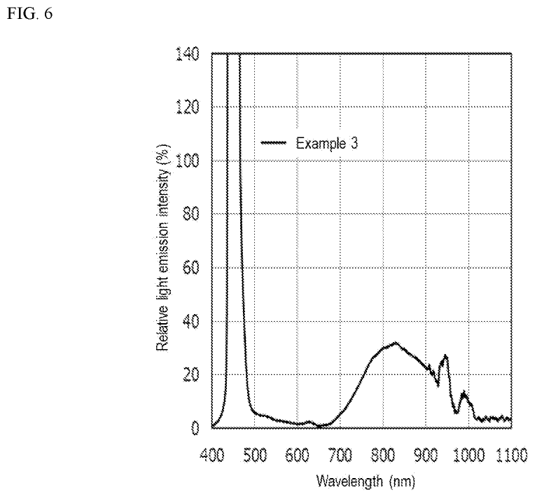

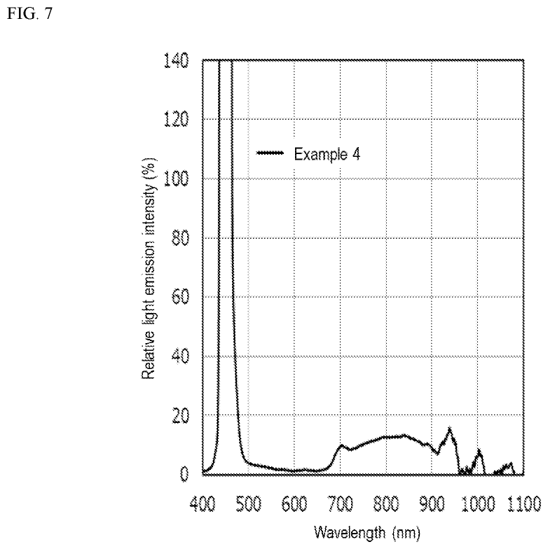

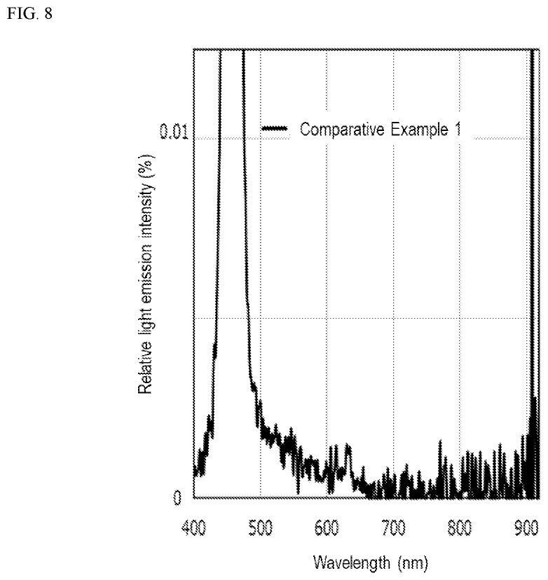

The light emission spectra of the oxide fluorescent material in each Example and the oxide in Comparative Example 1 were measured using a quantum efficiency measurement system (QE-2000, manufactured by Otsuka Electronics Co., Ltd.). The light emission peak wavelength of the excitation light used in the quantum efficiency measurement system was 450 nm. From the obtained light emission spectrum of each fluorescent material, the relative light emission intensity, the light emission peak wavelength, and the full width at half maximum were determined as light emission characteristics. That is, in the light emission spectrum of each fluorescent material, the light emission peak wavelength (λp) (nm) and the full width at half maximum (FWHM) (nm) of the light emission peak in the range of 700 nm or more and 1,050 nm or less were determined. Further, the light emission intensity at the light emission peak wavelength of the oxide fluorescent material according to Example 1 was defined as 100%, and the relative light emission intensity (%) at the light emission peak wavelength of the oxide fluorescent material according to each of Examples 2 to 4 was measured. The oxide in Comparative Example 1 emitted no light. The results are shown in Table 1. FIGS. 4 to 7 each show the light emission spectrum of the oxide fluorescent material according to each of Examples 1 to 4. The light emission spectrum of the oxide in Comparative Example 1 was also measured in the same manner. FIG. 8 shows the light emission spectrum of the oxide in Comparative Example 1. In each of FIGS. 4 to 8, the light emission spectrum having a light emission peak wavelength of 400 nm or more and 500 nm or less is the light emission spectrum of the excitation light source.

### Measurement of Excitation Spectrum

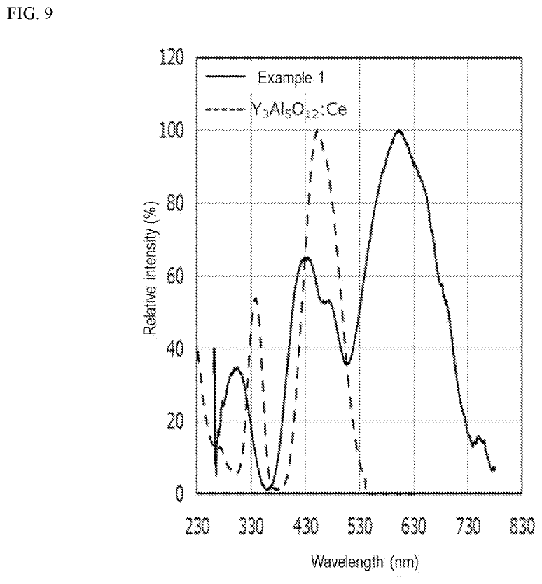

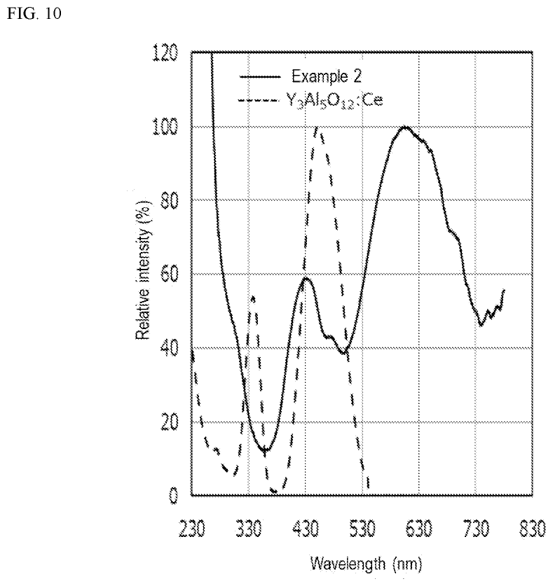

For the oxide fluorescent materials in Examples 1 and 2, and an aluminate fluorescent material (Y₃Al₅O₁₂:Ce) having the composition represented by the formula (3b-2) described later to be used in the light emitting device according to Comparative Example 1 described later, the excitation spectrum was measured in a range of 230 nm or more and 780 nm or less at the light emission peak wavelength of each oxide fluorescent material, at room temperature (20° C. to 25° C.) using a fluorescence spectrophotometer (F-4500, manufactured by Hitachi High-Technologies Corp.). The maximum intensity of the excitation spectrum of each oxide fluorescent material was defined as 100%, and the relative intensity (%) at each wavelength was used as the excitation spectrum pattern. FIG. 9 shows the excitation spectra of the oxide fluorescent material according to Example 1 and the aluminate fluorescent material (Y₃Al₅O₁₂:Ce). FIG. 10 shows the excitation spectra of the oxide fluorescent material according to Example 2 and the aluminate fluorescent material (Y₃Al₅O₁₂:Ce).

### Measurement of Reflection Spectrum

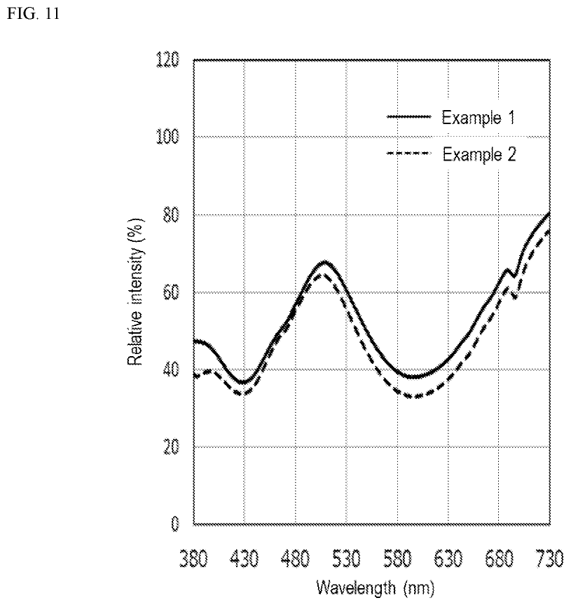

For the oxide fluorescent materials in Examples 1 and 2, the reflection spectrum was measured in a range of 380 nm or more and 730 nm or less at room temperature (20° C. to 25° C.) using a fluorescence spectrophotometer (F-4500, manufactured by Hitachi High-Technologies Corp.). Calcium hydrogenphosphate (CaHPO₄) was used for a reference sample. For each oxide fluorescent material, the reflectance of the reference sample was defined as 100%, and the relative intensity (%) at each wavelength was used as the reflection spectrum pattern. FIG. 11 shows the reflection spectra of the oxide fluorescent materials according to Examples 1 and 2.

TABLE 1

| | | Light emission characteristics | | |
|---|---|---|---|---|
| | | Relative | Light emission | Full width at |
| | | light emission | peak wavelength | half maximum |
| | | intensity | λp | (FWHM) |
| | Charged composition | (%) | (nm) | (nm) |
| Example 1 | Na₂SrGe₆O₁₄:Cr_{0.03} | 100.0 | 834 | 182 |
| Example 2 | Na₂CaGe₆O₁₄:Cr_{0.03} | 110.1 | 827 | 181 |
| Example 3 | K₂SrGe₆O₁₄:Cr_{0.03} | 33.3 | 826 | 195 |
| Example 4 | Li₂CaGe₆O₁₄:Cr_{0.03} | 15.1 | 841 | 200 |
| Comparative | Na₂CaSi₆O₁₄:Cr_{0.03} | 0.0 | — | — |
| Example 1 | | | | |

As shown in Table 1 or FIGS. 4 to 7, the oxide fluorescent materials according to Examples 1 to 4 had a light emission peak wavelength of 826 nm or more and 841 nm or less in the light emission spectrum, and had a full width at half maximum of 150 nm or more. The oxide fluorescent materials according to Examples 1 to 4 had a light emission peak wavelength in the wavelength range of red light to near-infrared light, and had a light emission spectrum with a wide full width at half maximum of 150 nm or more, more specifically 180 nm or more. The oxide according to Comparative Example 1 had a light emission intensity of 0%. As shown in FIG. 8, no light emission spectrum was observed in the oxide according to Comparative Example 1.

As shown in FIGS. 9 and 10, the oxide fluorescent materials according to Examples 1 and 2 had an intensity peak, respectively, in the range of 380 nm or more and 480 nm or less and in the range of 530 nm or more and 680 nm or less in the excitation spectrum. It can be seen that the oxide fluorescent materials according to Examples 1 and 2 emit light efficiently by the light emission in the wavelength range of 380 nm or more and 480 nm or less and in the range of 530 nm or more and 680 nm or less.

As shown in FIG. 11, it is found that the oxide fluorescent materials according to Examples 1 and 2 have relatively low reflectance of light in the range of 380 nm or more and 480 nm or less and in the range of 530 nm or more and 680 nm or less.

### Light Emitting Device According to Example

For the wavelength conversion member used in the light emitting device, fluorescent materials having the following charged compositions and having the following light emission peak wavelength when being excited by a light emitting element having a light emission peak wavelength of 450 nm, were used.

### First Fluorescent Material

Formula (1-1): Na₂CaGe₆O₁₄:Cr_{0.03}, light emission peak wavelength of 827 nm.

### Second Fluorescent Material

Formula (2a-1): Ca₁₀(PO₄)₆Cl₂:Eu, light emission peak wavelength of 450 nm.

### Third Fluorescent Material

Formula (3a-1): Ca₈MgSi₄O₁₆Cl₂:Eu, light emission peak wavelength of 520 nm;
Formula (3b-1): Lu₃Al₅O₁₂:Ce, light emission peak wavelength of 520 nm; and
Formula (3b-2): Y₃Al₅O₁₂:Ce, light emission peak wavelength of 560 nm.

### Fourth Fluorescent Material

Formula (4a): (Sr,Ca)AlSiN₃:Eu, light emission peak wavelength of 620 nm; and
Formula (4b): 3.5MgO·0.5MgF₂GeO₂:Mn, light emission peak wavelength of 658 nm.

### Fifth Fluorescent Material

Formula (5a): Ga₂O₃:Cr, light emission peak wavelength of 730 nm;
Formula (5e-1): NaSr₂ScGe₅O₁₄:Cr_{0.03}, light emission peak wavelength of 802 nm; and
Formula (5e-2): NaMg₂ScGe₅O₁₄:Cr_{0.03}, light emission peak wavelength of 897 nm.

### Light Emitting Device According to Example 1

The oxide fluorescent material according to Example 2 was used as the first fluorescent material. The second fluorescent material, the third fluorescent material, the fourth fluorescent material, and the fifth fluorescent material were mixed and dispersed with a silicone resin so as to have the composition shown in Table 2, and then defoamed to obtain a wavelength conversion member-forming composition. In Table 2, the formulation of the first fluorescent material, the second fluorescent material, the third fluorescent material, the fourth fluorescent material, and the fifth fluorescent material relative to 100 parts by mass of the resin is expressed in terms of parts by mass, in each Example and Comparative Example. The total content of the fluorescent materials in the wavelength conversion member-forming composition was 179.7 parts by mass relative to 100 parts by mass of the resin. Next, a molded body having a recessed portion was prepared as shown in FIG. 2; a light emitting element having a light emission peak wavelength of 420 nm and having a gallium nitride-based compound semiconductor was arranged at a first lead on the bottom surface of the recessed portion; and the wavelength conversion member-forming composition was then injected and filled over the light emitting element, followed by heating to cure the resin in the wavelength conversion member-forming composition. The full width at half maximum of the light emission spectrum of the light emitting element was 15 nm. A light emitting device according to Example 1 was produced through these steps.

### Light Emitting Devices According to Examples 2 and 3

Light emitting devices according to Examples 2 and 3 were produced in the same manner as the light emitting device according to Example 1 except that the wavelength conversion member-forming composition was prepared and used such that the blending amounts of the first fluorescent material, the second fluorescent material, the third fluorescent material, the fourth fluorescent material, and the fifth fluorescent material relative to 100 parts by mass of the resin were as shown in Table 2.

### Light Emitting Devices According to Examples 4 and 5

A fluorescent material having a composition represented by the formula (5e) was used for the fifth fluorescent material. Light emitting devices according to Examples 4 and 5 were produced in the same manner as the light emitting device according to Example 1 except that the wavelength conversion member-forming composition was prepared and used such that the blending amounts of the first fluorescent material, the second fluorescent material, the third fluorescent material, the fourth fluorescent material, and the fifth fluorescent material relative to 100 parts by mass of the resin were as shown in Table 2.

### Light Emitting Device According to Comparative Example

An aluminate fluorescent material having a composition represented by the formula (3b) was mixed and dispersed with a silicone resin, and then defoamed to obtain a wavelength conversion member-forming composition. The content of the fluorescent material in the wavelength conversion member-forming composition was 35 parts by mass relative to 100 parts by mass of the resin. A light emitting device was produced in the same manner as the light emitting device according to Example except that the above wavelength conversion member-forming composition was used and a light emitting element having a gallium nitride-based compound semiconductor with a light emission peak wavelength of 450 nm was used; and the light emitting device was used as a light emitting device according to Comparative Example.

### Measurement of Light Emission Spectrum

For the light emitting device according to each Example and Comparative Example, the light emission spectrum at room temperature (25° C.±5° C.) was measured using an optical measurement system combining a spectrophotometer (PMA-11, Hamamatsu Photonics K.K.) and an integral sphere. For each light emitting device, the maximum value of the light emission intensity in the range equal to or greater than the light emission peak wavelength of the light emitting element and equal to or less than 1,050 nm was defined as 100% in the light emission spectrum, and the minimum value of the relative light emission intensity in the range equal to or greater than the light emission peak wavelength of the light emitting element and equal to or less than 1,050 nm was determined (minimum value of relative light emission intensity (%)=minimum value of light emission intensity/maximum value of light emission intensity×100). The results are shown in Table 2.

TABLE 2

| | | | | | | | | | | | Light |
|---|---|---|---|---|---|---|---|---|---|---|---|
| | Fluorescent material | | | | | | | | | | emitting |
| | First | Second | | | | | | | | | device |
| | fluorescent | fluorescent | | | | | | | | | Minimum |
| | material | material | Third fluorescent | | | Fourth fluorescent | | Fifth fluorescent | | | value of |
| | (parts by | (parts by | material | | | material | | material | | | relative |
| | mass) | mass) | (parts by mass) | | | (parts by mass) | | (parts by mass) | | | light |
| | (1-1) | (2a-1) | (3a-1) | (3b-1) | (3b-2) | (4a) | (4b) | | (5e-1) | (5e-2) | emission |
| | Na₂CaGe₆ | Ca₁₀(PO₄)₆ | Ca₈MgSi₄ | Lu₃Al₅ | Y₃Al₅ | (Sr,Ca)AlSi | 3.5MgO•0.5Mg | (5a) | NaSr₂ScGe₅ | NaMg₂ScGe₅ | intensity |
| | O₁₄:Cr_{0.03} | Cl₂:Eu | O₁₆Cl₂:Eu | O₁₂:Ce | O₁₂:Ce | N₃:Eu | F₂•GeO₂:Mn | Ga₂O₃:Cr | O₁₄:Cr_{0.03} | O₁₄:Cr_{0.03} | (%) |
| Example 1 | 55.0 | 60.0 | 3.7 | 29.8 | — | 2.7 | 3.5 | 25.0 | — | — | 13.2 |
| Example 2 | 45.0 | 60.0 | 3.0 | 23.8 | — | 4.1 | 5.3 | 20.0 | — | — | 16.4 |
| Example 3 | 35.0 | 60.0 | 3.7 | 29.8 | — | 5.4 | 7.0 | 15.0 | — | — | 10.1 |
| Example 4 | 40.0 | 60.0 | 3.7 | 29.8 | — | 2.7 | 3.5 | 25.0 | 10.0 | — | 11.1 |
| Example 5 | 40.0 | 60.0 | 3.7 | 29.8 | — | 2.7 | 3.5 | 25.0 | — | 20.0 | 18.3 |
| Com- | — | — | — | — | 35.0 | — | — | — | — | — | 0.0 |
| parative | | | | | | | | | | | |
| Example 1 | | | | | | | | | | | |

The light emitting devices according to Examples 1 to 5 emitted light in which when the maximum value of the relative light emission intensity in the range of 420 nm or more and 1,050 nm or less was 100%, the minimum value of the relative light emission intensity in the range of 420 nm or more and 1,050 nm or less was 10% or more in the light emission spectra. In the light emitting device according to Comparative Example 1, the minimum value of the relative light emission intensity was almost 0% in the wavelength range of 800 nm or more in the light emission spectrum.

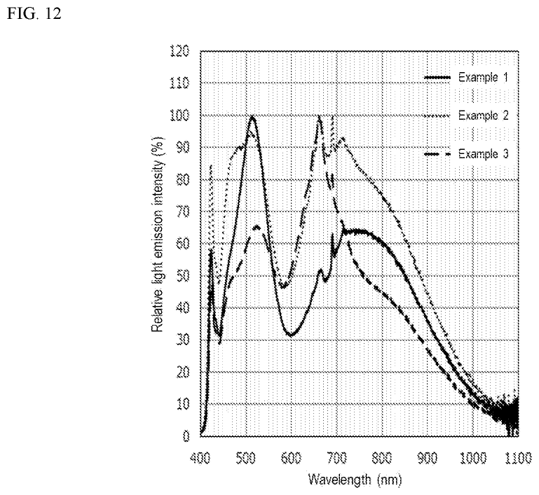

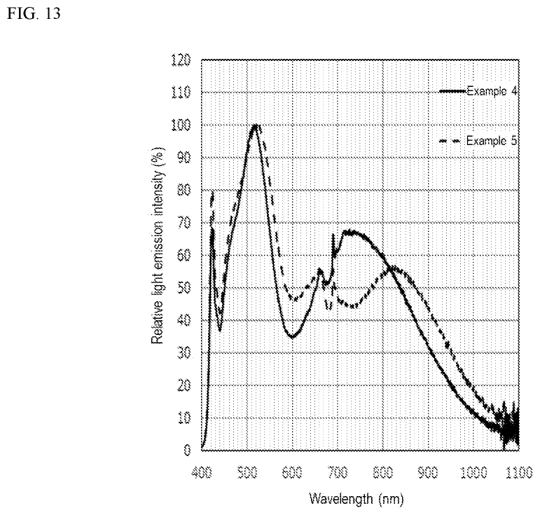

FIG. 12 is a graph showing the light emission spectrum of each of the light emitting devices according to Examples 1 to 3. FIG. 13 is a graph showing the light emission spectrum of each of the light emitting devices according to Examples 4 and 5.

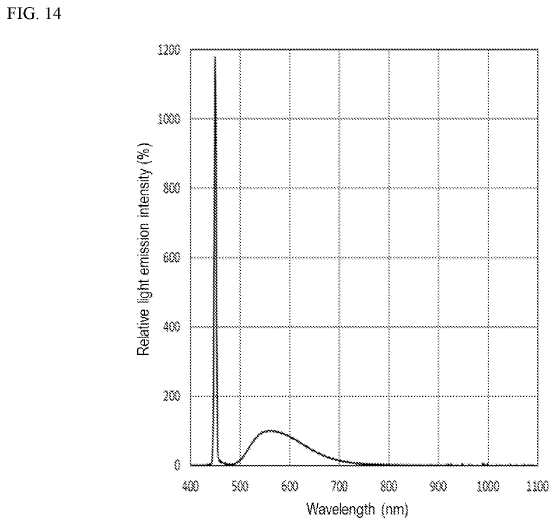

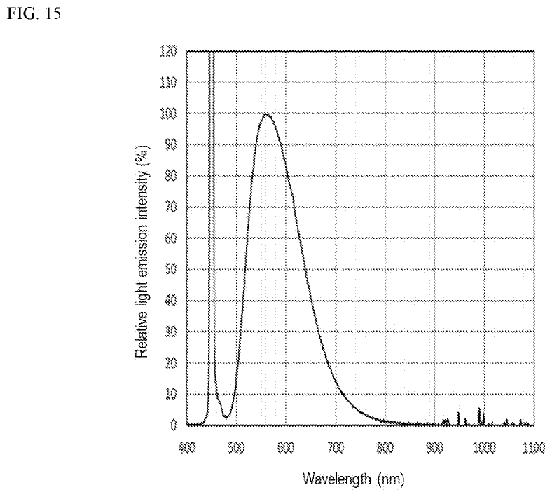

FIG. 14 is a graph showing the light emission spectrum of the light emitting device according to Comparative Example, and FIG. 15 is an enlarged graph of the light emission spectrum in which the light emission intensity (vertical axis) of the light emitting device according to Comparative Example is enlarged. The light emitting device according to Comparative Example emits white mixed light. Within the range of 450 nm (the light emission peak wavelength of the light emitting element) or more and 1,050 nm or less, the light emitting device according to Comparative Example had a light emission spectrum having a portion with 0% of the light emission intensity in the wavelength range of 900 nm or more. From the light emission spectrum of the light emitting device according to Comparative Example, it was confirmed that almost no light was emitted in the range of 900 nm or more and 1,050 nm, which was included in the near-infrared wavelength range.

### INDUSTRIAL APPLICABILITY

The oxide fluorescent material according to the present disclosure can be used in light emitting devices for medical use to obtain information in living bodies, light emitting devices to be mounted on small mobile devices such as smartphones to manage physical conditions, light emitting devices for analyzers to non-destructively measure the internal information of foods such as fruits and vegetables and rice, light emitting devices for plant cultivation to affect the photoreceptors of plants, and light emitting devices for reflection spectroscopic measuring devices used for measuring film thickness. The light emitting device using the oxide fluorescent material according to the present disclosure can be used in medical devices, small mobile devices, analyzers, plant cultivation systems, and reflection spectroscopic measuring devices.

### DENOTATIONS OF REFERENCE NUMERALS

10: Light emitting element, 11: Semiconductor element, 20: First lead, 30: Second lead, 40: Molded body, 42: Resin portion, 50, 51: Wavelength conversion member, 52: Wavelength conversion body, 53: Light-transmissive body, 60: Wire, 61: Conductive member, 70: Fluorescent material, 71: First fluorescent material, 72: Second fluorescent material, 73: Third fluorescent material, 74: Fourth fluorescent material, 75: Fifth fluorescent material, 80: Adhesive layer, 90: Covering member, and 100, 200: Light emitting device.

1. An oxide fluorescent material having a composition that comprises:
a first element M¹ being at least one element selected from the group consisting of Li, Na, K, Rb, and Cs;
a second element M² being at least one element selected from the group consisting of Ca, Sr, Mg, Ba, and Zn;
Ge;
O (oxygen); and
Cr,
the composition optionally comprising: a third element M³ being at least one element selected from the group consisting of Si, Ti, Zr, Sn, Hf, and Pb; and a fourth element M⁴ being at least one element selected from the group consisting of Eu, Ce, Tb, Pr, Nd, Sm, Yb, Ho, Er, Tm, Ni, and Mn,
wherein when the molar ratio of Ge, or the total molar ratio of the third element M³ and Ge in the case of comprising the third element M³, in 1 mol of the composition of the oxide fluorescent material is 6, the molar ratio of the first element M¹ is 1.5 or more and 2.5 or less, the molar ratio of the second element M² is 0.7 or more and 1.3 or less, the molar ratio of the third element M³ is 0 or more and 0.4 or less, the molar ratio of O (oxygen) is 12.9 or more and 15.1 or less, and the molar ratio of Cr is 0.2 or less, and
wherein the oxide fluorescent material has a light emission peak wavelength of 700 nm or more and 1,050 nm or less in a light emission spectrum of the oxide fluorescent material.

2. The oxide fluorescent material according to claim 1, having a composition included in a compositional formula represented by the following formula (1):
M¹ₜM²ᵤ(Ge₁₋ᵥM³ᵥ)₆O_{w}:Crₓ,M⁴_{y} (1)
wherein t, u, v, w, x, and y each satisfy 1.5≤t≤2.5, 0.7≤u≤1.3, 0≤v≤0.4, 12.9≤w≤15.1, 0<x≤0.2, 0≤y≤0.10, and y<x.

3. The oxide fluorescent material according to claim 1, wherein
the first element M¹ is at least one element selected from the group consisting of Li, Na, and K,
the second element M² comprises at least one element selected from the group consisting of Ca and Sr as an essential element, the second element M² optionally further comprising at least one element selected from the group consisting of Mg, Ba, and Zn,
the composition optionally comprises the third element M³ being at least one element selected from the group consisting of Si, Ti, Zr, Sn, Hf, and Pb, and the fourth element M⁴ being at least one element selected from the group consisting of Yb, Nd, Tm, and Er.

4. The oxide fluorescent material according to claim 1, having a full width at half maximum of 150 nm or more in the light emission spectrum having the light emission peak wavelength.

5. A light emitting device comprising the oxide fluorescent material according to claim 1 and a light emitting element having a light emission peak wavelength of 365 nm or more and 500 nm or less to irradiate the oxide fluorescent material with light.

6. The light emitting device according to claim 5, comprising
a first fluorescent material containing the oxide fluorescent material, and
at least one fluorescent material selected from the group consisting of a second fluorescent material having a light emission peak wavelength of 455 nm or more and less than 495 nm, a third fluorescent material having a light emission peak wavelength of 495 nm or more and less than 610 nm, a fourth fluorescent material having a light emission peak wavelength of 610 nm or more and less than 700 nm, and a fifth fluorescent material having a light emission peak wavelength of 700 nm or more and 1,050 nm or less,
wherein the light emitting device has a light emission spectrum having, when a maximum value of a light emission intensity of the light emission peak wavelength of the light emitting element or more and 1,050 nm or less is 100%, a minimum value of the light emission intensity in the range equal to or greater than the light emission peak wavelength of the light emitting element and equal to or less than 1,050 nm being 10% or more.

7. The light emitting device according to claim 6, wherein the second fluorescent material comprises at least one fluorescent material selected from the group consisting of a phosphate fluorescent material having a composition included in a compositional formula represented by the following formula (2a), an aluminate fluorescent material having a composition included in a compositional formula represented by the following formula (2b), and an aluminate fluorescent material having a composition represented by the following formula (2c):
(Ca,Sr,Ba,Mg)₁₀(PO₄)₆(F,Cl,Br,I)₂:Eu (2a),
(Ba,Sr,Ca)MgAl₁₀O₁₇:Eu (2b), and
Sr₄Al₁₄O₂₅:EU (2c).

8. The light emitting device according to claim 6, wherein the third fluorescent material comprises at least one fluorescent material selected from the group consisting of a silicate fluorescent material having a composition included in a compositional formula represented by the following formula (3a), an aluminate fluorescent material or a gallate fluorescent material having a composition included in a compositional formula represented by the following formula (3b), a β-SiAlON fluorescent material having a composition included in a compositional formula represented by the following formula (3c), a cesium lead halide fluorescent material having a composition included in a compositional formula represented by the following formula (3d), and a nitride fluorescent material having a composition included in a compositional formula represented by the following formula (3e):
(Ca,Sr,Ba)₈MgSi₄O₁₆(F,Cl,Br)₂:Eu (3a),
(Lu,Y,Gd,Tb)₃(Al,Ga)₅O₁₂:Ce (3b),
Si_{6-z}Al_{z}O_{z}N_{8-z}:Eu (0<z≤4.2) (3c),
CsPb(F,Cl,Br)₃ (3d), and
(La,Y,Gd)₃Si₆N₁₁:Ce (3e).

9. The light emitting device according to claim 6, wherein the fourth fluorescent material comprises at least one fluorescent material selected from the group consisting of a nitride fluorescent material having a composition included in a compositional formula represented by the following formula (4a), a fluoro-germanate fluorescent material having a composition represented by the following formula (4b), an oxynitride fluorescent material having a composition included in a compositional formula represented by the following formula (4c), a fluoride fluorescent material having a composition included in a compositional formula represented by the following formula (4d), a fluoride fluorescent material having a composition included in a compositional formula represented by the following formula (4e), a nitride fluorescent material having a composition included in a compositional formula represented by the following formula (4f), and a nitride fluorescent material having a composition included in a compositional formula represented by the following formula (4g):
(Sr,Ca)AlSiN₃:Eu (4a),
3.5MgO·0.5MgF₂·GeO₂:Mn (4b),
(Ca,Sr,Mg)ₖSi₁₂₋₍ₘ₊ₙ₎Alₘ₊ₙOₙN₁₆₋ₙ:Eu (4c),
wherein k, m, and n each satisfy 0<k≤2.0, 2.0≤m≤6.0, and 0≤n≤2.0,
A_{c}[M⁶_{1-b}Mn⁴⁺_{b}F_{d}] (4d),
wherein A includes at least one selected from the group consisting of K⁺, Li⁺, Na⁺, Rb⁺, Cs⁺, and NH₄⁺; M⁶ includes at least one element selected from the group consisting of Group 4 elements and Group 14 elements; b satisfies 0<b<0.2; c represents the absolute value of the charge of [M⁶_{1-b}Mn⁴⁺_{b}F_{d}]ions; and d satisfies 5<d<7,
A′_{c′}[M^{6′}_{1-b′}Mn⁴⁺_{b′}F_{d′}] (4e),
wherein A′ includes at least one selected from the group consisting of K⁺, Li⁺, Na⁺, Rb⁺, Cs⁺, and NH₄⁺; M^{6′} includes at least one element selected from the group consisting of Group 4 elements, Group 13 elements, and Group 14 elements; b′ satisfies 0<b′<0.2; c′ represents the absolute value of the charge of [M^{6′}_{1-b′}Mn⁴⁺_{b′}F_{d′}] ions; and d′ satisfies 5<d′<7,
(Ba,Sr,Ca)₂Si₅N₈:Eu (4f), and
(Sr,Ca)LiAl₃N₄:Eu (4g).

10. The light emitting device according to claim 6, wherein the fifth fluorescent material comprises at least one fluorescent material selected from the group consisting of a gallate fluorescent material having a composition represented by the following formula (5a), an aluminate fluorescent material having a composition represented by the following formula (5b), a gallate fluorescent material having a composition represented by the following formula (5c), an aluminate fluorescent material having a composition included in a compositional formula represented by the following formula (5d), and a fluorescent material having a composition included in a compositional formula represented by the following formula (5e):
Ga₂O₃:Cr (5a),
Al₂O₃:Cr (5b),
ZnGa₂O₄:Cr (5c),
(Lu,Y,Gd,Tb)₃(Al,Ga)₅O₁₂:Ce,Cr (5d), and
M⁷_{g}M⁸ₕM⁹ᵢM¹⁰₅Oⱼ:Crₑ,M¹¹_{f} (5e),
wherein M⁷ is at least one element selected from the group consisting of Li, Na, Ka, Rb, and Cs; M⁸ is at least one element selected from the group consisting of Mg, Ca, Sr, Ba, and Zn; M⁹ is at least one element selected from the group consisting of Ba, Al, Ga, In and rare earth elements; M¹⁰ is at least one element selected from the group consisting of Si, Ti, Ge, Zr, Sn, Hf, and Pb; M¹¹ is at least one element selected from the group consisting of Eu, Ce, Tb, Pr, Nd, Sm, Yb, Ho, Er, Tm, Ni, and Mn; and e, f, g, h, i, and j satisfy 0<e≤0.2, 0≤f≤0.1, f<e, 0.7≤g≤1.3, 1.5≤h≤2.5, 0.7≤i≤1.3, and 12.9≤j≤15.1.

11. A method for producing an oxide fluorescent material comprising:
preparing a first compound containing a first element M¹ being at least one element selected from the group consisting of Li, Na, K, Rb, and Cs, a second compound containing a second element M² being at least one element selected from the group consisting of Ca, Sr, Mg, Ba, and Zn, a fifth compound containing Ge, a sixth compound containing Cr, optionally a third compound containing a third element M³ being at least one element selected from the group consisting of Si, Ti, Ge, Zr, Sn, Hf, and Pb, and optionally a fourth compound containing a fourth element M⁴ being at least one element selected from the group consisting of Eu, Ce, Tb, Pr, Nd, Sm, Yb, Ho, Er, Tm, Ni, and Mn;
adjusting and mixing the first compound, the second compound, the fifth compound, the sixth compound, and optionally the third compound and/or the fourth compound to prepare a raw material mixture such that, when the molar ratio of Ge, or the total molar ratio of the third element M³ and Ge in the case of comprising the third element M³, in 1 mol of the composition of the oxide fluorescent material is 6, the molar ratio of the first element M¹ is 1.5 or more and 2.5 or less, the molar ratio of the second element M² is 0.7 or more and 1.3 or less, and the molar ratio of Cr is 0.2 or less; and
heat-treating the raw material mixture at a temperature 900° C. or higher and 1,200° C. or lower in an atmosphere containing oxygen to obtain an oxide fluorescent material,
wherein at least one selected from the group consisting of the first compound, the second compound, the fifth compound, and the sixth compound is an oxide.

12. The method for producing an oxide fluorescent material according to claim 11, wherein the raw material mixture has a composition included in a compositional formula represented by the following formula (1):
M¹ₜM²ᵤ(Ge₁₋ᵥM³ᵥ)₆O_{w}:Crₓ,M⁴_{y} (1)
wherein t, u, v, w, x, and y satisfy 1.5≤t≤2.5, 0.7≤u≤1.3, 0≤v≤0.4, 12.9≤w≤15.1, 0<x≤0.2, 0≤y≤0.10, and y<x.

13. The method for producing an oxide fluorescent material according to claim 11, wherein the heat-treating is carried out in an air atmosphere.

14. The method for producing an oxide fluorescent material according to claim 11, wherein the heat-treating is carried out at a temperature of 950° C. or higher and 1,150° C. or lower.
